(19) United States
(12) Patent Application Publication
(10) Pub. No.: US 2017/0219923 A1
(43) Pub. Date: Aug. 3, 2017

(54) PHOTOSENSITIVE RESIN COMPOSITION, PHOTOSENSITIVE FILM, PATTERN SUBSTRATE, PHOTOSENSITIVE CONDUCTIVE FILM, AND CONDUCTIVE PATTERN SUBSTRATE

(71) Applicants: HITACHI CHEMICAL COMPANY, LTD., Tokyo (JP); SHANGHAI JIAO TONG UNIVERSITY, Shanghai-Shi (CN)

(72) Inventors: Emiko OOTA, Chiyoda-ku, Tokyo (JP); Masahiko EBIHARA, Chiyoda-ku, Tokyo (JP); Yasuharu MURAKAMI, Chiyoda-ku, Tokyo (JP); Xuesong JIANG, Minhang District, Shanghai (CN)

(21) Appl. No.: 15/328,255

(22) PCT Filed: Jul. 22, 2015
(86) PCT No.: PCT/JP2015/070859

§ 371 Date: Jan. 23, 2017

(30) Foreign Application Priority Data
Jul. 24, 2014 (JP) 2014-150809

(51) Int. Cl. G03F 7/031; B32B 38/10; G03F 7/11; B32B 27/36; B32B 37/00; B32B 37/20; B32B 27/08; B32B 27/32

(52) U.S. Cl. CPC G03F 7/031; B32B 27/08; B32B 38/10; B32B 27/32; B32B 27/36; B32B 37/0053; B32B 37/203; G03F 7/11; B32B 2255/10; B32B 2255/26; B32B 2310/0831; B32B 2255/205; B32B 2307/202; B32B 2457/202; B32B 2250/244; B32B 2250/24; B32B 2323/04; B32B 2367/00

(57) ABSTRACT

A photosensitive resin composition, comprising a binder polymer, a photopolymerizable compound, and a photopolymerization initiator, wherein the photopolymerization initiator contains a compound represented by the following general formula (1):

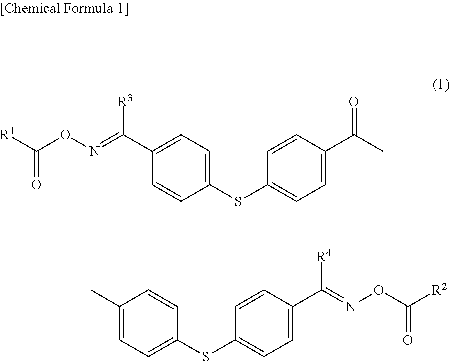

[In the formula (1), R¹, R², R³ and R⁴ each independently represent an alkyl group, an aryl group, an aralkyl group, —OR⁵, —COOR⁶ or —OCOR⁷; and R⁵, R⁶ and R⁷ each independently represent an alkyl group, an aryl group or an aralkyl group.]

### TECHNICAL FIELD

The present invention relates to a photosensitive resin composition, a photosensitive film, a patterned substrate, a photosensitive conductive film, and a conductive patterned substrate.

### BACKGROUND ART

Liquid crystal display elements or touch panels (touch screens) are used as display devices for large electronic apparatuses such as personal computer and television sets, small electronic apparatuses such as car navigation systems, mobile phones and electronic dictionaries, and OA and FA apparatuses.

A variety of methods are already put into practical use as touch panels; recently, use of capacitive touch panels has been promoted. In the capacitive touch panels, when a finger tip (conductor) contacts the touch input surface, the finger tip and a conductive film are capacitively coupled to form a capacitor. In such capacitive touch panels, the coordinates of the contact position are detected by detecting a change in charges in the contact position by the finger tip.

In particular, projected capacitive touch panels can perform complex instructions because these enable multipoint detection of finger tips, and have good operationability. Because of such good operationability, use of the projected capacitive touch panels is promoted as input devices on display screens in apparatuses having small display devices such as mobile phones and portable music players.

In the projected capacitive touch panels, in general, to express two-dimensional coordinates of an X-axis and a Y-axis, a plurality of X electrodes and a plurality of Y electrodes orthogonal to the X electrodes form a two-layered structure. As a material forming the electrodes, a material for a transparent conductive film or the like is used.

The frame region of the touch panel is a region where the touch position cannot be detected. For this reason, it is important to narrow the area of the frame region for improving the value of the product. A metal wire for transmitting the detection signal of the touch position needs to be disposed in the frame region; to narrow the frame area, the width of the metal wire needs to be narrowed.

However, when the touch panel is brought into contact with the finger tip or the like, corrosive components such as moisture and salt invade into the inside of the touch panel from a sensing region. When the corrosive components invade into the inside of the touch panel, the metal wire may corrode to cause an increase in electric resistance between electrodes and a circuit for driving or disconnection therebetween.

A projected capacitive touch panel having an insulating layer formed on a metal to protect corrosion of the metal wire is known (for example, see Patent Literature 1 below). In such a touch panel, a silicon dioxide layer is formed on the metal by plasma chemical vapor deposition (plasma CVD) to prevent corrosion of the metal. However, such a method needs a high temperature treatment because plasma CVD is used, and has problems, i.e., the substrate is limited or production cost increases.

A method using a photosensitive resin composition is known as the method of preparing a protective film in a display device such as a touch panel, instead of plasma CVD. For example, a method of disposing a photosensitive layer comprising a photosensitive resin composition on a predetermined substrate, and exposing and developing the photosensitive layer is known as a method of disposing a protective film (for example, a resist film) in a required place (for example, see Patent Literature 2 below). Cost reduction can be expected in preparation of a protective film with a photosensitive resin composition, compared to plasma CVD.

Recently, attempts to form transparent conductive patterns using a material instead of indium oxide tin (ITO), indium oxide, tin oxide, or the like as a material for a transparent conductive film have been known. For example, a method of forming a conductive pattern using a photosensitive conductive film comprising a support film, a conductive layer disposed on the support film and containing conductive fibers, and a photosensitive layer disposed on the conductive layer and containing a photosensitive resin composition is proposed (for example, see Patent Literature 3 below). Using such a technique, a conductive pattern can be directly and simply formed on a variety of substrates in a photolithographing step.

### CITATION LIST

### Patent Literature

Patent Literature 1: Japanese Unexamined Patent Publication No. 2011-28594

Patent Literature 2: International Publication No. WO2013/084873

Patent Literature 3: International Publication No. WO2013/051516

### SUMMARY OF INVENTION

### Technical Problem

In cases where a protective film or a transparent conductive film for a touch panel is prepared using a photosensitive resin composition, for the photosensitive resin composition, high sensitivity is required to achieve high throughput, and obtaining a pattern having high transparency is required.

Moreover, to provide a display device such as a touch panel in the form of a thin film, it is preferred that the photosensitive layer comprising a photosensitive resin composition is as thin as possible. However, in cases where a photosensitive layer comprising a conventional photosensitive resin composition, having a thickness of 15 μm or less, is formed on a substrate, there is room for improvement to satisfy high sensitivity and high transparency (for example, colorless, highly transparent pattern forming ability) at the same time.

An object of the present invention is to provide a photosensitive resin composition that can satisfy high sensitivity and high transparency at the same time even if a thin photosensitive layer is formed. Moreover, another object of the present invention is to provide a photosensitive film using the photosensitive resin composition, a patterned substrate, a photosensitive conductive film, and a conductive patterned substrate.

### Solution to Problem

The present inventors, who have conducted extensive research to solve the problems above, have found that high sensitivity and high transparency can be satisfied at the same time by use of a photosensitive resin composition comprising a specific photopolymerization initiator even if a thin photosensitive layer is formed, and have completed the present invention.

Specific aspects of the present invention are shown below.

<1> A photosensitive resin composition, comprising a binder polymer, a photopolymerizable compound, and a photopolymerization initiator,
wherein the photopolymerization initiator contains a compound represented by the following general formula (1):

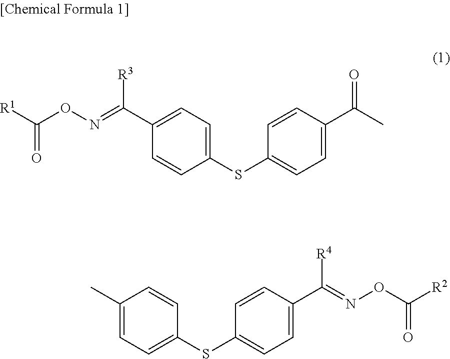

[In the formula (1), R¹, R², R³ and R⁴ each independently represent an alkyl group, an aryl group, an aralkyl group, —OR⁵, —COOR⁶ or —OCOR⁷; and R⁵, R⁶ and R⁷ each independently represent an alkyl group, an aryl group or an aralkyl group.]
<2> A photosensitive resin composition, comprising a photopolymerizable compound and a photopolymerization initiator,
wherein the photopolymerization initiator contains a compound represented by the following general formula (1):

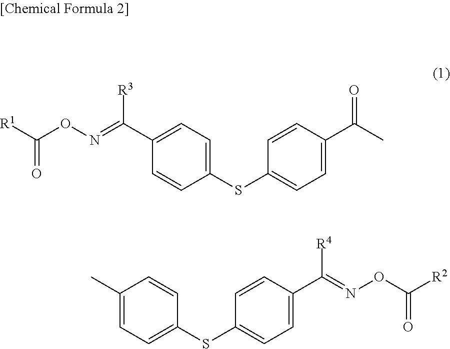

[In the formula (1), R¹, R², R³ and R⁴ each independently represent an alkyl group, an aryl group, an aralkyl group, —OR⁵, —COOR⁶ or —OCOR⁷; and R⁵, R⁶ and R⁷ each independently represent an alkyl group, an aryl group or an aralkyl group.]
<3> A photosensitive film, comprising a support film, and a photosensitive layer disposed on the support film,
wherein the photosensitive layer comprises the photosensitive resin composition according to <1> or <2>.
   <4> The photosensitive film according to <3>, wherein the thickness of the photosensitive layer is 15 μm or less.
   <5> A patterned substrate, comprising a substrate, and a pattern disposed on the substrate,
wherein the pattern comprises a cured product of the photosensitive resin composition according to <1> or <2>.
   <6> A patterned substrate, comprising a substrate, and a pattern disposed on the substrate,
wherein the pattern comprises a cured product of the photosensitive resin composition of the photosensitive film according to <3> or <4>.
   <7> A photosensitive conductive film for forming a conductive pattern, comprising:
a support film, a conductive layer disposed on the support film, and a photosensitive layer disposed on the conductive layer,
wherein the photosensitive layer comprises the photosensitive resin composition according to <1> or <2>.
   <8> A photosensitive conductive film for forming a conductive pattern, comprising:
a support film, a photosensitive layer disposed on the support film, and a conductive layer disposed on the photosensitive layer,
wherein the photosensitive layer comprises the photosensitive resin composition according to <1> or <2>.
   <9> The photosensitive conductive film according to <7> or <8>, wherein the thickness of the photosensitive layer is 15 μm or less.
   <10> A photosensitive conductive film according to any one of <7> to <9>, wherein the conductive layer comprises conductive fibers.
   <11> The photosensitive conductive film according to <10>, wherein the conductive fibers contain silver fibers.
   <12> A conductive patterned substrate, comprising a substrate, and a conductive pattern disposed on the substrate,
wherein the conductive pattern comprises a cured product of the photosensitive resin composition of the photosensitive conductive film according to any one of <7> to <11>.

### Advantageous Effects of Invention

According to the present invention, it is possible to provide a photosensitive resin composition that can satisfy high sensitivity and high transparency at the same time even if a thin photosensitive layer is formed. Moreover, the present invention can provide a photosensitive film using the photosensitive resin composition, a patterned substrate, a photosensitive conductive film, and a conductive patterned substrate.

According to the present invention, it is possible to provide applications of a photosensitive resin composition or its cured product to display devices. According to the present invention, it is possible to provide applications of a photosensitive resin composition or its cured product to touch panels. According to the present invention, it is possible to provide applications of a photosensitive resin composition or its cured product to transparent electrodes (for example, transparent electrodes in electronic components). According to the present invention, it is possible to provide applications of a photosensitive resin composition or its cured product to protective films (for example, protective films in electronic components).

### BRIEF DESCRIPTION OF DRAWINGS

FIG. 1 is a schematic sectional view illustrating an embodiment of the photosensitive film.

FIG. 2 is a schematic sectional view illustrating an embodiment of the photosensitive conductive film.

FIG. 3 is a schematic sectional view for describing an embodiment of the method of producing a pattern.

FIG. 4 is a schematic sectional view for describing an embodiment of the method of producing an electronic component.

FIG. 5 is a schematic plan view illustrating an embodiment of the electronic component.

FIG. 6 is a partial sectional view illustrating an embodiment of the electronic component.

FIG. 7 is a schematic plan view illustrating an embodiment of the electronic component.

FIG. 8 is a schematic plan view illustrating an embodiment of the electronic component.

FIG. 9 is a partially cut-out perspective view of FIG. 8.

FIG. 10 is a partial sectional view taken along the line X-X of FIG. 9.

FIG. 11 is a partially cut-out perspective view for describing an embodiment of the method of producing an electronic component.

FIG. 12 is a partial sectional view for describing an embodiment of the method of producing an electronic component.

FIG. 13 is a partial plan view illustrating an embodiment of the electronic component.

### DESCRIPTION OF EMBODIMENTS

Hereinafter, embodiments of the present invention will be described in detail. It should be noted that the present invention is not limited to the embodiments below.

Throughout the specification, “(meth)acrylic acid” indicates acrylic acid or methacrylic acid. The same is true in other similar terms such as “(meth)acrylate.” Moreover, “A or B” may include one of A and B, or may include both A and B. Furthermore, unless otherwise specified, exemplary materials may be used singly or may be used in combination.

Moreover, throughout the specification, the term “step” includes not only independent steps but also steps that are not clearly distinguished from other steps but achieve predetermined actions of the steps. Throughout the specification, ranges of numeric values represented by using the term “to” indicate ranges including the numeric values before and after “to” as the minimum values and maximum values.

Furthermore, throughout the specification, in cases where there is a plurality of substances corresponding to each component in a composition, the content of the component in the composition indicates the total amount of the plurality of substances present in the composition, unless otherwise specified.

<Photosensitive Resin Composition>

The photosensitive resin composition of a first embodiment comprises (A) a binder polymer (hereinafter, referred to as “component (A)” in some cases), (B) a photopolymerizable compound (hereinafter, referred to as “component (B)” in some cases), and (C) a photopolymerization initiator (hereinafter, referred to as “component (C)” in some cases), and the (C) photopolymerization initiator contains (c1) a compound represented by the following general formula (1) (hereinafter, referred to as “component (c1)” in some cases). The photosensitive resin composition of a second embodiment comprises the component (B) and the component (C), and the component (C) contains the component (c1).

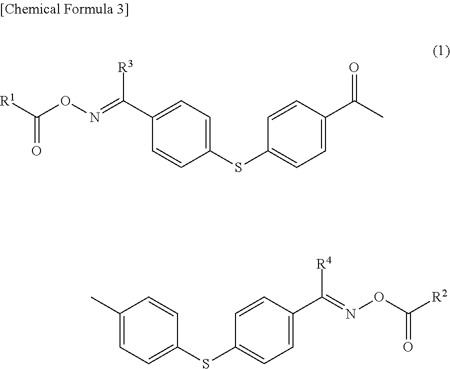

[In the formula (1), R¹, R², R³ and R⁴ each independently represent an alkyl group, an aryl group, an aralkyl group, —OR⁵, —COOR⁶ or —OCOR⁷; and R⁵, R⁶ and R⁷ each independently represent an alkyl group, an aryl group or an aralkyl group.]

According to the photosensitive resin composition of the present embodiment (the first embodiment and the second embodiment. The same is true below.), high sensitivity and high transparency can be satisfied at the same time even if a thin photosensitive layer (for example, a thin layer (such as a protective film) having a thickness of 15 μm or less) is formed. Thereby, a pattern having high transparency can be obtained.

The present inventors consider the reason that the advantageous effects are obtained by the photosensitive resin composition of the present embodiment as follows. First, because a photoreaction using mainly light in the ultraviolet range to the visible light range is used in conventional photosensitive resin compositions, photopolymerization initiators absorbing light including the visible light range are often used. Moreover, an increase in the amount of the photopolymerization initiator absorbing light including the visible light range is needed to obtain high sensitivity. However, it is considered that yellowing occurs due to the photopolymerization initiator by irradiation with active light beams having a large amount of energy, and it is difficult to ensure transparency.

In contrast, in the present embodiment, the above-mentioned specific photopolymerization initiator absorbs low amount of light in the visible light range, has an absorption wavelength overlapping the spectrum of light in the ultraviolet light range from a high pressure mercury lamp or the like, and has photobleaching properties indicating that the absorption of light in the visible light range is reduced by exposure to light. It is inferred that thereby, while yellowing is reduced, the absorption efficiency is increased to promote the photoreaction, and therefore, high sensitivity and high transparency can be satisfied at the same time.

In the photosensitive resin composition of the first embodiment, examples of the component (A) include (meth)acrylic resins, styrene resins, epoxy resins, amide resins, amide epoxy resins, alkyd resins, phenol resins, ester resins, urethane resins, epoxy (meth)acrylate resins obtained by a reaction of epoxy resins with (meth)acrylic acid, and acid-modified epoxy (meth)acrylate resins obtained by a reaction of epoxy (meth)acrylate resins with acid anhydrides.

As the component (A), (meth)acrylic resins are preferred from the viewpoint of high alkali developability and film formability. Examples of the (meth)acrylic resins include copolymers having at least one selected from structural units (also referred to as “structure unit.” The same is true in the term “structural unit” below) derived from (a1) (meth)acrylic acid (hereinafter, referred to as “component (a1)” in some cases) and structural units derived from (a2) alkyl (meth)acrylate esters (hereinafter, referred to as “component (a2)” in some cases); copolymers having a structural unit derived from (a1) (meth)acrylic acid and a structural unit derived from (a2) alkyl (meth)acrylate esters are preferred.

The content (content ratio) of the structural unit derived from the component (a1) is preferably 10% by mass or more, more preferably 12% by mass or more based on the total mass of the structural units forming the component (A) from the viewpoint of high alkali developability. The content of the structural unit derived from the component (a1) is preferably 50% by mass or less, more preferably 40% by mass or less, still more preferably 30% by mass or less, particularly preferably 25% by mass or less based on the total mass of the structural units forming the component (A) from the viewpoint of high alkali resistance.

Examples of the component (a2) include methyl (meth)acrylate, ethyl (meth)acrylate, propyl (meth)acrylate, butyl (meth)acrylate, 2-ethylhexyl (meth)acrylate, and hydroxylethyl (meth)acrylate.

The content of the structural unit derived from the component (a2) is preferably 90% by mass or less, more preferably 89% by mass or less, still more preferably 88% by mass or less based on the total mass of the structural units forming the component (A).

The copolymer may further have a structural unit derived from other monomer copolymerizable with the component (a1) or the component (a2).

Examples of other monomers copolymerizable with the component (a1) or the component (a2) include tetrahydrofurfuryl (meth)acrylate, dimethylaminoethyl (meth)acrylate, diethylaminoethyl (meth)acrylate, glycidyl (meth)acrylate, benzyl (meth)acrylate, 2,2,2-trifluoroethyl (meth)acrylate, 2,2,3,3-tetrafluoropropyl (meth)acrylate, (meth)acrylamide, (meth)acrylonitrile, diacetone (meth)acrylamide, styrene, and vinyltoluene.

The weight average molecular weight of the component (A) is preferably 10,000 or more, more preferably 15,000 or more, still more preferably 30,000 or more, particularly preferably 40,000 or more from the viewpoint of high resolution. The weight average molecular weight of the component (A) is preferably 200,000 or less, more preferably 150,000 or less, still more preferably 100,000 or less from the viewpoint of high resolution. The weight average molecular weight can be measured by gel permeation chromatography with reference to Examples in this specification.

The content of the component (A) in the photosensitive resin composition of the first embodiment is preferably 35% by mass or more, more preferably 40% by mass or more, still more preferably 50% by mass or more, particularly preferably 55% by mass or more based on the total amount of the component (A) and the component (B) from the viewpoint of forming a pattern having higher transparency. The content of the component (A) is preferably 85% by mass or less, more preferably 80% by mass or less, still more preferably 70% by mass or less, particularly preferably 65% by mass or less based on the total amount of the component (A) and the component (B) from the viewpoint of further enhancing sensitivity and achieving sufficient mechanical strength.

As the photopolymerizable compounds which is the component (B), a photopolymerizable compound having an ethylenically unsaturated group can be used, for example.

Examples of the photopolymerizable compound having an ethylenically unsaturated group include monofunctional vinyl monomers, bifunctional vinyl monomers, and polyfunctional vinyl monomers having at least three ethylenically unsaturated groups.

Examples of the monofunctional vinyl monomers include (meth)acrylic acid and alkyl (meth)acrylate esters exemplified as the monomers used in synthesis of the copolymer used as the component (A), and monomers copolymerizable therewith.

Examples of the bifunctional vinyl monomers include polyethylene glycol di(meth)acrylate, trimethylolpropane di(meth)acrylate, polypropylene glycol di(meth)acrylate, 2,2-bis(4-(meth)acryloxypolyethoxypolypropoxyphenyl)propane, bisphenol A diglycidyl ether di(meth)acrylate, and esterified products of compounds having a hydroxyl group and an ethylenically unsaturated group (such as β-hydroxyethyl acrylate and (β-hydroxyethyl methacrylate) and polyvalent carboxylic acids (such as phthalic anhydride).

Examples of the polyfunctional vinyl monomers having at least three ethylenically unsaturated groups include compounds obtained by a reaction of polyhydric alcohols with α,β-unsaturated carboxylic acids (such as acrylic acid and methacrylic acid), such as trimethylolpropane tri(meth)acrylate, tetramethylolmethane tri(meth)acrylate, tetramethylolmethane tetra(meth)acrylate, dipentaerythritol penta(meth)acrylate, dipentaerythritol hexa(meth)acrylate and ditrimethylolpropane tetra(meth)acrylate; compounds obtained by an addition reaction of glycidyl group-containing compounds with α,β-unsaturated carboxylic acids, such as trimethylolpropane triglycidyl ether tri(meth)acrylate; and compounds obtained by an addition reaction of diglycerols with α,β-unsaturated carboxylic acids, such as diglycerol (meth)acrylate.

Among these, the polyfunctional vinyl monomers having at least three ethylenically unsaturated groups are preferred; from the viewpoint of high readiness in development, (meth)acrylate compounds having a skeleton derived from pentaerythritol, (meth)acrylate compounds having a skeleton derived from dipentaerythritol or (meth)acrylate compounds having a skeleton derived from trimethylolpropane are more preferred, (meth)acrylate compounds having a skeleton derived from dipentaerythritol or (meth)acrylate compounds having a skeleton derived from trimethylolpropane are still more preferred, (meth)acrylate compounds having a skeleton derived from trimethylolpropane are particularly preferred.

Here, the term “(meth)acrylate compound having a skeleton derived from” will be described using an example of a (meth)acrylate compound having a skeleton derived from trimethylolpropane.

The (meth)acrylate compound having a skeleton derived from trimethylolpropane indicates an esterified product of trimethylolpropane and (meth)acrylic acid, and the esterified product can include compounds modified with an alkyleneoxy group. As the esterified product, compounds having the maximum number of ester bonds of 3 in one molecule are preferred; compounds having 1 to 2 ester bonds may be mixed. Moreover, as the (meth)acrylate compound having a skeleton derived from trimethylolpropane, a compound obtained by dimerizing a trimethylolpropane di(meth)acrylate compound may be used.

In cases where the monomer having at least three ethylenically unsaturated groups is used in combination with a monofunctional vinyl monomer or a bifunctional vinyl monomer, the proportion of these monomers used is not particularly limited; from the viewpoint of achieving high photo-curability and ability of preventing corrosion of electrodes, the proportion of the structural unit derived from the monomer having at least three ethylenically unsaturated groups is preferably 30% by mass or more, more preferably 50% by mass or more, still more preferably 75% by mass or more based on the total amount of the photopolymerizable compounds contained in the photosensitive resin composition.

The content of the component (B) in the photosensitive resin composition of the first embodiment is preferably 15% by mass or more, more preferably 20% by mass or more, still more preferably 30% by mass or more, particularly preferably 35% by mass or more based on the total amount of the component (A) and the component (B) from the viewpoint of high photo-curability and coating property. The content of the component (B) is preferably 65% by mass or less, more preferably 60% by mass or less, still more preferably 50% by mass or less, particularly preferably 45% by mass or less based on the total amount of the component (A) and the component (B) from the viewpoint of high storage stability in the case of rolled film.

As the contents of the component (A) and the component (B) in the photosensitive resin composition of the first embodiment, it is preferred that the component (A) is 35 to 85% by mass and the component (B) is 15 to 65% by mass, it is more preferred that the component (A) is 40 to 80% by mass and the component (B) is 20 to 60% by mass, it is still more preferred that the component (A) is 50 to 70% by mass and the component (B) is 30 to 50% by mass, it is particularly preferred that the component (A) is 55 to 65% by mass and the component (B) is 35 to 45% by mass, based on the total amount of the component (A) and the component (B). When the contents of the component (A) and the component (B) are within these ranges, sufficient sensitivity is readily achieved while application property or the film formability of the photosensitive film is sufficiently ensured, and photo-curability and developability can be sufficiently ensured.

In the photosensitive resin composition of the present embodiment, the (C) photopolymerization initiator contains the (c1) compound represented by the following general formula (1) (oxime ester compounds). By use of such a photosensitive resin composition, a pattern having high transparency can be formed while high sensitivity is achieved.

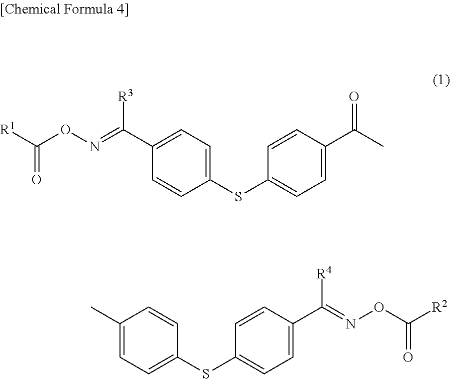

[In the formula (1), R¹, R², R³ and R⁴ each independently represent an alkyl group, an aryl group, an aralkyl group, —OR⁵, —COOR⁶ or —OCOR⁷; and R⁵, R⁶ and R⁷ each independently represent an alkyl group, an aryl group or an aralkyl group.]

As described above, R¹, R², R³ and R⁴ may be —OR⁵, —COOR⁶ or —OCOR⁷, namely, an alkyl group, an aryl group and an aralkyl group in R¹, R², R³ and R⁴ may be interrupted by an ether bond or an ester bond. The number of carbon atoms in the alkyl group is preferably 9 or less, more preferably 6 or less, still more preferably 3 or less from the viewpoint of achieving higher sensitivity. The number of carbon atoms in the alkyl group is preferably 1 or more from the viewpoint of readiness in synthesis. Examples of the aryl group include a phenyl group, a tolyl group and a naphthyl group. Examples of the aralkyl group include a benzyl group and a phenethyl group.

From the viewpoint of satisfying high sensitivity and high transparency at the same time at a higher level, it is preferred that at least one of R¹, R², R³ and R⁴ is an alkyl group, it is more preferred that all of R¹, R², R³ and R⁴ are an alkyl group.

The component (c1) can be synthesized by the following method, for example. First, 4,4′-difluorobenzophenone is reacted with thiophenol to yield a phenyl sulfide compound. Furthermore, a carboxylic chloride is reacted to yield an acyl product. Subsequently, hydroxylamine is reacted in the presence of hydrochloric acid and sodium acetate to yield an oxime product. Finally, carboxylic anhydride is reacted to yield an oxime ester product. R¹, R², R³ and R⁴ can be varied by selecting a carboxylic chloride, a carboxylic anhydride, or the like. The synthetic method is not limited to the method described above.

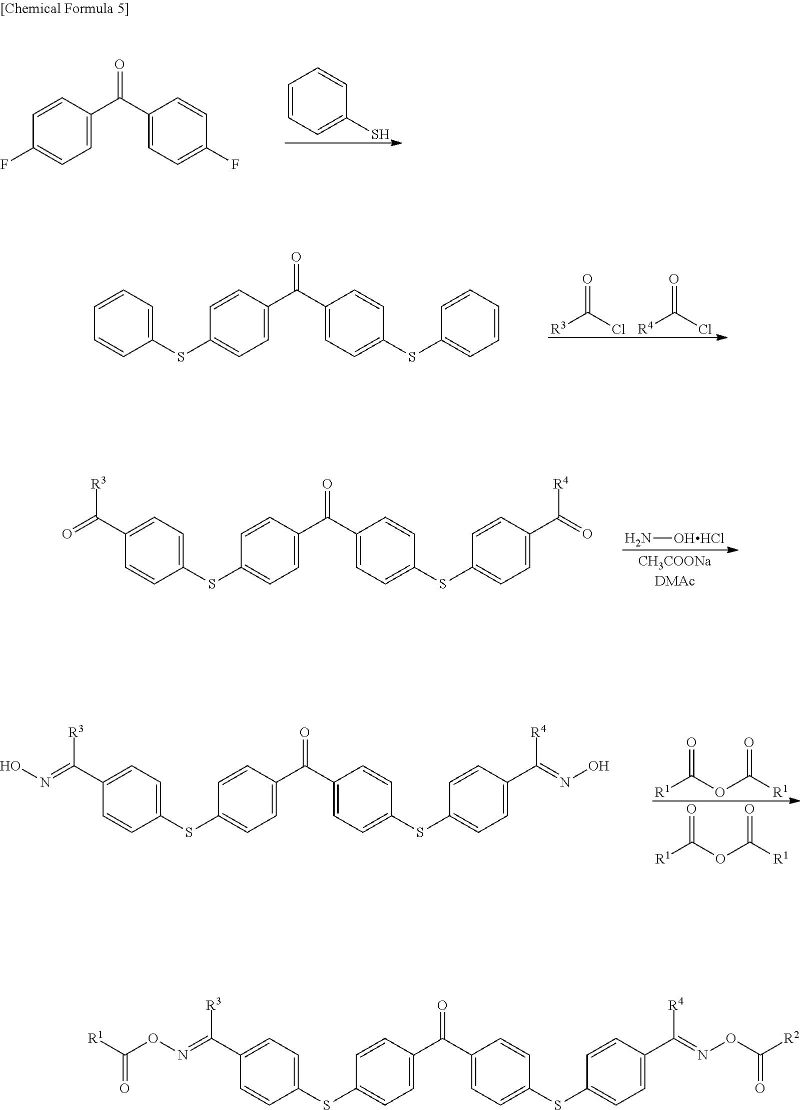

The (C) photopolymerization initiator in the photosensitive resin composition of the present embodiment can further contain (c2) a photopolymerization initiator other than the component (c1) (hereinafter, referred to as “component (c2)” in some cases). Examples of the component (c2) include aromatic ketones such as benzophenone, 4-(dimethylamino)-4′-methoxybenzophenone, 2-benzyl-2-dimethylamino-1-(4-morpholinophenyl)-1-butanone, 2-methyl-1-[4-(methylthio)phenyl-2-morpholino-1-propanone; oxime ester compounds such as 1-[4-(phenylthio)phenyl]-1,2-octanedione 2-(O-benzoyloxime), 1-[9-ethyl-6-(2-methylbenzoyl)-9H-carbazol-3-yl]ethanone O-acetyloxime; phosphine oxide compounds such as diphenyl-2,4,6-trimethylbenzoylphosphine oxide; and benzyl derivatives such as benzyl dimethyl ketal.

The content of the component (c1) in the photosensitive resin composition of the present embodiment is preferably 0.7% by mass or more, more preferably 2% by mass or more, still more preferably 3% by mass or more based on the content of the component (B) from the viewpoint of higher photosensitivity and resolution. The content of the component (c1) is preferably 30% by mass or less, more preferably 15% by mass or less, still more preferably 8% by mass or less based on the content of the component (B) from the viewpoint of high transmittance of visible light.

The content of the component (c1) in the photosensitive resin composition of the first embodiment is preferably 0.1% by mass or more, more preferably 0.5% by mass or more, still more preferably 1.0% by mass or more based on the total amount of the component (A) and the component (B) from the viewpoint of higher photosensitivity and resolution. The content of the component (c1) is preferably 20% by mass or less, more preferably 10% by mass or less, still more preferably 5% by mass or less based on the total amount of the component (A) and the component (B) from the viewpoint of high transmittance of visible light.

The content of the photopolymerization initiator (the total content of the content of the component (c1) and the content of the component (c2)) in the photosensitive resin composition of the present embodiment is preferably 0.7% by mass or more, more preferably 2% by mass or more, still more preferably 3% by mass or more based on the content of the component (B) from the viewpoint of higher photosensitivity and resolution. The content of the photopolymerization initiator is preferably 30% by mass or less, more preferably 15% by mass or less, still more preferably 8% by mass or less based on the content of the component (B) from the viewpoint of high transmittance of visible light.

The content of the photopolymerization initiator (the total content of the content of the component (c1) and the content of the component (c2)) in the photosensitive resin composition of the first embodiment is preferably 0.1% by mass or more, more preferably 0.5% by mass or more, still more preferably 1.0% by mass or more based on the total amount of the component (A) and the component (B) from the viewpoint of higher photosensitivity and resolution. The content of the photopolymerization initiator is preferably 20% by mass or less, more preferably 10% by mass or less, still more preferably 5% by mass or less based on the total amount of the component (A) and the component (B) from the viewpoint of high transmittance of visible light.

The photosensitive resin composition of the present embodiment can comprise an ultraviolet absorbing agent, an adhesiveness-imparting agent (such as a silane coupling agent), a leveling agent, a plasticizer, a filler, an antifoaming agent, a flame retardant, a stabilizer, an antioxidant, fragrances, a thermal crosslinking agent, a polymerization inhibitor, and the like when necessary. The content of each additive is, for example, about 0.05 to 30% by mass based on the content of the component (B) in the photosensitive resin composition of the present embodiment, and is about 0.01 to 20% by mass based on the total amount of the component (A) and the component (B) in the photosensitive resin composition of the first embodiment.

The minimum value of the transmittance of visible light at 400 to 700 nm in the photosensitive resin composition of the present embodiment is preferably 85% or more, more preferably 92% or more, still more preferably 95% or more from the viewpoint of achieving high image display quality in a sensing region and preventing color degradation.

The b* in the CIELAB color system in the photosensitive resin composition of the present embodiment is preferably −0.2 or more, more preferably 0.0 or more, still more preferably 0.1 or more. The b* in the CIELAB color system in the photosensitive resin composition of the present embodiment is preferably 1.0 or less, more preferably 0.8 or less, still more preferably 0.7 or less. When b* is −0.2 or more or 1.0 or less, high image display quality in a sensing region is achieved and color degradation can be prevented in the same way as in the minimum value of the transmittance of visible light. The b* in the CIELAB color system can be measured with a spectrocolorimeter with reference to Examples in this specification.

The photosensitive resin composition of the present embodiment can be used to form a photosensitive layer on a substrate (such as a film or glass). For example, a coating solution obtained by homogeneously dissolving or dispersing the photosensitive resin composition in a solvent is applied onto a substrate to form a coating film, and the solvent is then removed by drying; thereby, a photosensitive layer can be formed.

The solvent is not particularly limited, and a known solvent can be used; it is preferred that methyl ethyl ketone, ethylene glycol monobutyl ether acetate, diethylene glycol monoethyl ether acetate, diethylene glycol diethyl ether, diethylene glycol ethyl methyl ether, diethylene glycol dimethyl ether, propylene glycol monomethyl ether, propylene glycol monomethyl ether acetate, or the like is used.

Examples of the application method include doctor blade coating, Meyer bar coating, roll coating, screen coating, spin coating, inkjet coating, spray coating, dip coating, gravure coating, curtain coating, and die coating.

The drying conditions are not particularly limited; the drying temperature is preferably 60 to 130° C., and the drying time is preferably 0.5 to 30 minutes.

It is preferred that the photosensitive resin composition of the present embodiment is formed into a film and used as a photosensitive films. The method of laminating a photosensitive film on a substrate can significantly shorten the production step and reduce cost for the reason that a roll-to-roll process can be readily achieved, the step of drying the solvent can be shortened, for example.

<Photosensitive Film>

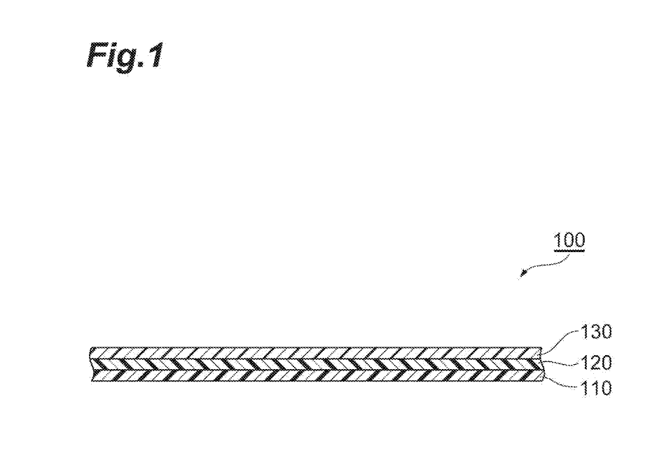

FIG. 1 is a schematic sectional view illustrating a photosensitive film of the present embodiment. A photosensitive film 100 illustrated in FIG. 1 comprises a support film 110, a photosensitive layer 120 disposed on the support film 110, and a protective film (cover film) 130 disposed on the photosensitive layer 120. The protective film 130 is disposed at opposite side of the support film 110 via the photosensitive layer 120. The photosensitive layer 120 comprises the photosensitive resin composition of the present embodiment, and may be a layer consisting of the photosensitive resin composition of the present embodiment.

As the support film 110, a polymer film can be used. Examples of the polymer film include polyethylene terephthalate films, polycarbonate films, polyethylene films, polypropylene films, and polyethersulfone films.

The thickness of the support film 110 is preferably within the following range from the viewpoint of ensuring coating properties and readily preventing a reduction in sensitivity during irradiation with active light beams through the support film 110. The thickness of the support film 110 is preferably 5 μm or more, more preferably 10 μm or more, still more preferably 15 μm or more, particularly preferably 20 μm or more. The thickness of the support film 110 is preferably 300 μm or less, more preferably 200 μm or less, still more preferably 100 μm or less, particularly preferably 50 μm or less.

The photosensitive layer 120 can be formed by preparing a coating solution consisting of the photosensitive resin composition of the present embodiment, applying this coating solution onto the support film 110, and drying the coating solution. The coating solution can be obtained by homogeneously dissolving or dispersing the components consisting the photosensitive resin composition of the present embodiment described above in a solvent.

Although the thickness (thickness after drying) of the photosensitive layer is varied according to the application, the following range is preferred. The thickness of the photosensitive layer is preferably 1 μm or more from the viewpoint of readiness in formation of a layer (such as coating). The thickness of the photosensitive layer is preferably 200 μm or less, more preferably 15 μm or less, still more preferably 10 μm or less from the viewpoint of preventing insufficient sensitivity due to a reduction in transmittance of light to attain sufficient photo-curability of the photosensitive layer to be transferred. The thickness of the photosensitive layer is preferably 15 μm or less from the viewpoint of providing a touch panel in the form of a thin film and a less prominent pattern on the substrate, and may be more than 15 μm. The thickness of the photosensitive layer can be measured with a scanning electron microscope.

As the protective film 130, a polymer film can be used. Examples of the polymer film include polyethylene films, polypropylene films, polyethylene terephthalate films, polycarbonate films, polyethylene-vinyl acetate copolymer films, and laminated films thereof (for example, laminated films of polyethylene-vinyl acetate copolymer films and polyethylene films).

The thickness of the protective film 130 is preferably about 5 to 100 μm. The thickness of the protective film 130 is preferably 70 μm or less, more preferably 60 μm or less, still more preferably 50 μm or less, particularly preferably 40 μm or less because the protective film can be rolled into a roll and be suitably stored.

The photosensitive film of the present embodiment can be rolled into a roll and stored or used as a photosensitive film roll. The photosensitive film roll comprises a roll core and a photosensitive film wound around the roll core; the photosensitive film is the photosensitive film of the present embodiment.

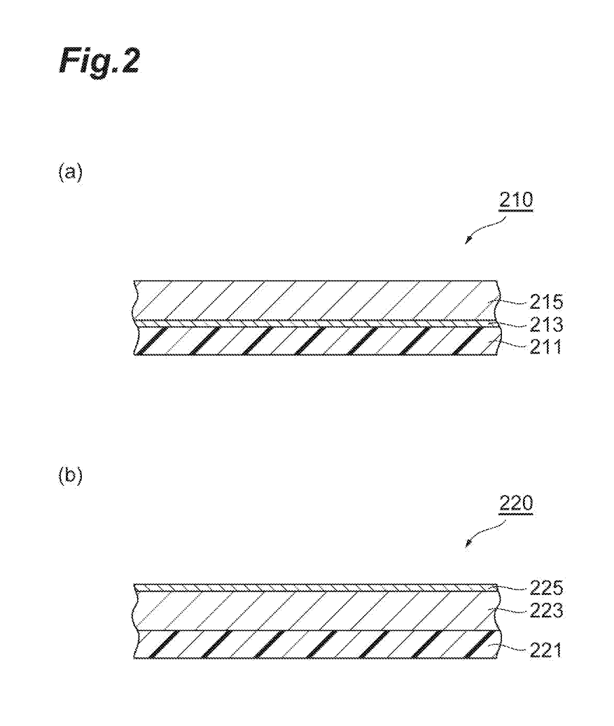

The photosensitive film of the present embodiment may be used as a photosensitive conductive film having a conductive layer on the photosensitive layer at the support film side or the protective film side thereof. FIG. 2 is a schematic sectional view illustrating the photosensitive conductive film of the present embodiment.

As illustrated in FIG. 2(a), a photosensitive conductive film (photosensitive film) 210 of the first embodiment comprises a support film 211, a conductive layer 213 disposed on the support film 211, and a photosensitive layer (photosensitive resin layer) 215 disposed on the conductive layer 213. As illustrated in FIG. 2(b), a photosensitive conductive film (photosensitive film) 220 of the second embodiment comprises a support film 221, a photosensitive layer 223 disposed on the support film 221, and a conductive layer 225 disposed on the photosensitive layer 223. The photosensitive conductive films 210 and 220 are, for example, photosensitive conductive films for forming a conductive pattern by transfer (lamination) on a substrate (such as a film or glass). With respect to the photosensitive conductive film 220, a conductive pattern may be formed on the support film 221 using the support film 221 as a substrate.

The photosensitive layers 215 and 223 comprise the photosensitive resin composition of the present embodiment, and may be a layer consisting of the photosensitive resin composition of the present embodiment. Moreover, the conductive layers 213 and 225 may comprise the photosensitive resin composition of the present embodiment.

As the conductive layer, a layer having conductivity can be used without limitation in particular. It is preferred that the conductive layer contains at least one of conductive fibers, for example.

Examples of the conductive fibers include metal fibers of gold, silver, platinum or the like; and carbon fibers such as carbon nanotubes. As the conductive fibers, gold fibers or silver fiber are preferred from the viewpoint of high conductivity. As the conductive fibers, silver fibers are more preferred because the conductivity of the conductive layer can be readily controlled.

Metal fibers can be prepared, for example, by a method of reducing metal ions with a reducing agent such as NaBH₄ or a polyol method. Moreover, as carbon nanotubes, commercially available products such as Hipco monolayer carbon nanotubes from Unidym, Inc. can be used.

The fiber diameter of the conductive fibers is preferably 1 nm or more, more preferably 2 nm or more, still more preferably 3 nm or more. The fiber diameter of the conductive fibers is preferably 50 nm or less, more preferably 20 nm or less, still more preferably 10 nm or less. The fiber length of the conductive fibers is preferably 1 μm or more, more preferably 2 μm or more, still more preferably 3 μm or more. The fiber length of the conductive fibers is preferably 100 μm or less, more preferably 50 μm or less, still more preferably 10 μm or less. The fiber diameter and the fiber length can be measured with a scanning electron microscope.

In the conductive layer, an organic conductor may be used instead of the conductive fibers, or the conductive fibers and an organic conductor may be used in combination. The organic conductor can be used without limitation in particular; polymers such as thiophene derivatives and aniline derivatives and the like are preferred. Specifically, examples thereof include polyethylenedioxythiophene, polyhexylthiophene and polyaniline.

Although the thickness of the conductive layer is varied according to the application of the conductive pattern formed using the photosensitive conductive film or required conductivity, the following range is preferred. The thickness of the conductive layer is preferably 1 μm or less, more preferably 0.5 μm or less, still more preferably 0.1 μm or less from the viewpoint of high light transmittance (for example, light transmittance in the wavelength band at 400 to 700 nm) and high pattern formability suitable for preparation of transparent electrodes. The thickness of the conductive layer is preferably 1 nm or more, more preferably 5 nm or more. The thickness of the conductive layer can be measured with a scanning electron microscope photograph.

The conductive layer can be formed, for example, by applying (such as coating) a coating solution (such as a conductive dispersion liquid) onto a support film or a photosensitive layer laminated on the support film, and then drying the coating solution. The coating solution can be obtained by mixing the conductive fibers or the organic conductor describe above with water or an organic solvent. The coating solution may comprise a dispersion stabilizer, such as a surfactant, and the like when necessary.

After drying, a laminate having a conductive layer formed may be laminated when necessary. Application (such as coating) can be performed by a known method such as roll coating, comma coating, gravure coating, air knife coating, die coating, bar coating, or spray coating. Drying can be performed in a hot air convection dryer or the like at 30 to 150° C. for about 1 to 30 minutes; in cases where the conductive layer comprises silver fibers, it is preferred that drying is performed at 5 to 35° C. In the conductive layer, the conductive fibers and the organic conductor may coexist with a surfactant or a dispersion stabilizer.

In the conductive layer, the conductive fibers and the organic conductor may be combined. In this case, a conductive layer may be formed by applying a coating solution obtained by mixing the conductive fibers and the organic conductor (such as a conductive dispersion liquid). Moreover, the conductive fibers and the organic conductor may be sequentially applied to form a conductive layer; for example, a solution of the organic conductor can be applied to form a conductive layer after a dispersion liquid of the conductive fibers is applied.

The surface resistivity of the conductive layer is preferably 1000 Ω/square or less, more preferably 500 Ω/square or less, still more preferably 150 Ω/square or less from the viewpoint of effectively utilizing the conductive layer as a transparent electrode. The surface resistivity can be controlled by the concentration or the amount applied of the coating solution of the conductive fibers or the organic conductor, for example.

<Patterned Substrate, Conductive Patterned Substrate>

The patterned substrate of the present embodiment comprises a substrate, and a pattern disposed on the substrate, and the pattern comprises a cured product of the photosensitive resin composition of the present embodiment. The pattern may comprise a cured product of the photosensitive resin composition of the photosensitive film of the present embodiment. The pattern may be formed using the photosensitive film of the present embodiment, for example, it may be formed using a photosensitive resin composition of the photosensitive film.

The conductive patterned substrate of the present embodiment comprises a substrate, and a conductive pattern disposed on the substrate, and the conductive pattern comprises a cured product of the photosensitive resin composition of the photosensitive conductive film of the present embodiment. The conductive pattern may be formed using the photosensitive conductive film of the present embodiment, for example, it may be formed using a photosensitive resin composition of the photosensitive conductive film. A resin layer (such as a resin cured layer) may be disposed between the substrate and the conductive pattern. The conductive pattern comprises a cured product of the photosensitive layer or the conductive layer of the photosensitive conductive film of the present embodiment, and may be a conductive pattern consisting of a cured product of the photosensitive layer or the conductive layer of the photosensitive conductive film of the present embodiment.

The surface resistivity of the conductive pattern in the conductive patterned substrate of the present embodiment is preferably 1000 Ω/square or less, more preferably 500 Ω/square or less, still more preferably 150 Ω/square or less from the viewpoint of effectively utilizing the conductive pattern as a transparent electrode. The surface resistivity can be controlled by the concentration or the amount applied of the coating solution of the conductive fibers or the organic conductor, for example.

<Method of Producing Pattern>

The method of producing (forming) a pattern of the present embodiment comprises a transfer step (laminating step), an exposing step and a developing step in this order. Through these steps, a patterned substrate comprising a pattern obtained by patterning on the substrate or a conductive patterned substrate comprising a conductive pattern obtained by patterning on the substrate is obtained. Without subjecting the photosensitive conductive film to the transfer step, a conductive pattern may be formed on the support film by using the support film as a substrate.

Examples of the substrate include glass substrates; and plastic substrates of polycarbonate or the like. The minimum light transmittance of the substrate in the wavelength band at 400 to 700 nm is preferably 80% or more.

In cases where the photosensitive layer is located at the position of the outermost layer in the photosensitive film (for example, cases where the photosensitive film 100 or the photosensitive conductive film 210 is used), the photosensitive film is transferred (laminated) on the substrate in the transfer step in such a way as to achieve close adhesion of the photosensitive layer, for example. In cases where the conductive layer is located at the position of the outermost layer in the photosensitive film (for example, cases where the photosensitive conductive film 220 is used), the photosensitive film is transferred (laminated) on the substrate in the transfer step in such a way as to achieve close adhesion of the conductive layer, for example. In the cases where the photosensitive conductive film 220 is used, the support film 221 may be used as a substrate without performing transfer.

In the transfer step, for example, the photosensitive film can be transferred by press bonding the photosensitive layer side or the conductive layer side of the photosensitive film to the substrate while being heated. In cases where the photosensitive film comprises a protective film, the transfer step is performed after the protective film is removed. It is preferred that the transfer step is performed under reduced pressure from the viewpoint of high adhesion and followability. The transfer step of the photosensitive film is preferably performed by heating the outermost layer (photosensitive layer or conductive layer) or the substrate to 70 to 130° C. and the pressure at press bonding is preferably about 0.1 to 1.0 MPa (about 1 to 10 kgf/cm²); these conditions are not particularly limited. Moreover, although the substrate does not need to be preheated if the outermost layer is heated to 70 to 130° C. as described above, a preheat treatment of the substrate can also be performed to further improve laminating properties.

In the exposing step, for example, a predetermined portion of the photosensitive layer is irradiated with active light beams to form a photocured portion. In cases where the support film is transparent, the photosensitive layer may be irradiated with active light beams while the support film remains attached. In cases where the photosensitive conductive film is used, the exposing step may comprise a first exposing step of irradiating the photosensitive layer with active light beams while the support film remains attached, and a second exposing step of irradiating the photosensitive layer with active light beams after the support film is peeled off.

Examples of the exposing method in the exposing step include a method (masked exposing method) of irradiating with active light beams in the form of an image through a negative or positive photomask (mask pattern) called art work. As light sources for the active light beams, a known light source (for example, a light source effectively emitting ultraviolet light, visible light or the like, such as a carbon arc lamp, a mercury steam arc lamp, an ultra-high pressure mercury lamp, a high pressure mercury lamp or a xenon lamp) can be used. Moreover, a light source effectively emitting ultraviolet light, visible light or the like, such as an Ar ion laser or a semiconductor laser, can also be used. A light source effectively emitting visible light, such as a photoflood lamp for photographs or a sun lamp, can also be used. Moreover, a method of irradiating with active light beams in the form of an image by a direct drawing method using laser exposure or the like may also be used.

Although the amount of exposure in the exposing step is varied according to the apparatus or the composition of the photosensitive resin composition to be used, the following range is preferred. The amount of exposure is preferably 5 mJ/cm² or more, more preferably 10 mJ/cm² or more from the viewpoint of high photo-curability. The amount of exposure is preferably 1000 mJ/cm² or less, more preferably 200 mJ/cm² or less from the viewpoint of high resolution.

In the developing step, the exposed photosensitive layer is developed to form a pattern. In the developing step, for example, the entire photosensitive layer not exposed in the exposing step is removed. Moreover, in cases where the conductive layer is in contact with the photosensitive layer, the conductive layer is patterned together with the photosensitive layer.

Examples of the developing method include wet development. The wet development is performed by a known method such as spraying, reciprocal dipping, brushing or scrapping using a developing solution (such as an alkaline aqueous solution, an aqueous developing solution, or an organic solvent-based developing solution) corresponding to the photosensitive resin, for example.

As the developing solution, safe and stable developing solutions having high operationability (such as an alkaline aqueous solution) are used, for example. As a base for the alkaline aqueous solution, alkali hydroxides such as hydroxides of lithium, sodium and potassium; alkali carbonates such as a carbonate or bicarbonate of lithium, sodium, potassium or ammonium; alkali metal phosphates such as potassium phosphate and sodium phosphate; alkali metal pyrophosphates such as sodium pyrophosphate and potassium pyrophosphate; and the like are used.

As the alkaline aqueous solution used in development, an aqueous solution of 0.1 to 5% by mass sodium carbonate, an aqueous solution of 0.1 to 5% by mass potassium carbonate, an aqueous solution of 0.1 to 5% by mass sodium hydroxide, an aqueous solution of 0.1 to 5% by mass sodium tetraborate, and the like are preferred. The pH of the alkaline aqueous solution used in development is preferably in the range of 9 to 11. The temperature of the alkaline aqueous solution is adjusted according to the developability of the photosensitive layer. The alkaline aqueous solution may comprise a surfactant, an antifoaming agent, a small amount of organic solvent for proceeding development, and the like.

Examples of the development method include dipping, paddling, spraying (such as high pressure spraying), brushing, and scrapping. Among these, use of high pressure spraying is preferred from the viewpoint of improving resolution.

In the method of forming a pattern of the present embodiment, after development, the pattern may be further cured by performing heating at about 60 to 250° C. or exposing at about 0.2 to 10 J/cm² when necessary.

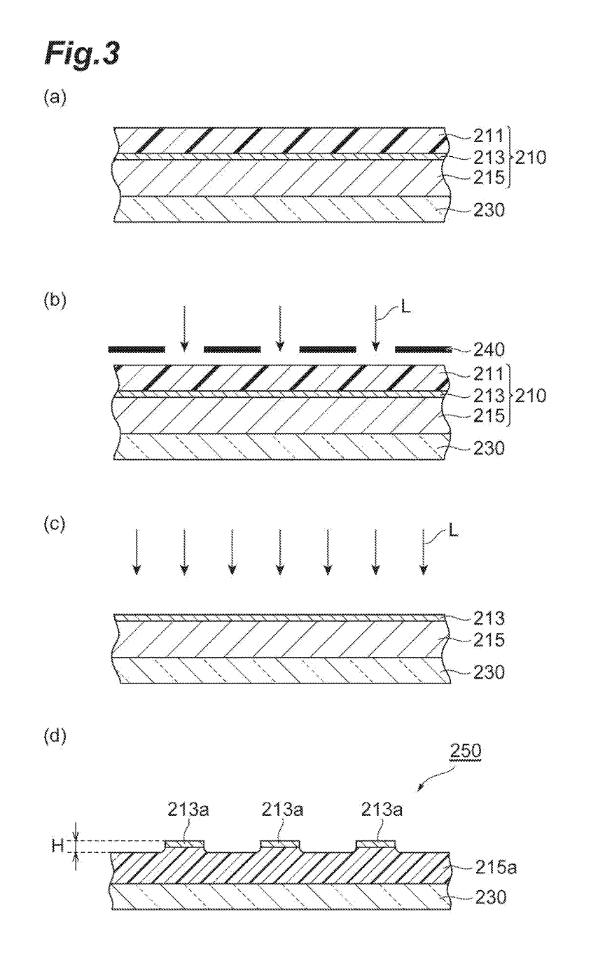

As one example of the method of producing a pattern of the present embodiment, a method of producing a conductive patterned substrate will be described using FIG. 3. FIG. 3 is a schematic sectional view for describing the method of producing a conductive pattern of the present embodiment. The method of producing a conductive pattern of the present embodiment comprises a transfer step, a first exposing step, a second exposing step, and a developing step in this order. In the transfer step, the photosensitive conductive film 210 is transferred onto the substrate 230 such that the photosensitive layer 215 is in contact with the substrate 230 (FIG. 3(a)). In the first exposing step, predetermined portions of the photosensitive layer 215 covered with the support film 211 are irradiated with active light beams through a photomask (mask pattern) 240 (FIG. 3(b)). In the second exposing step, after the support film 211 is peeled off, part or all of the exposed portions and unexposed portions of the first exposing step are irradiated with active light beams (FIG. 3(c)). In the developing step, the photosensitive layer 215 is developed after the second exposing step to obtain a conductive patterned substrate 250 having a conductive pattern 213a (FIG. 3(d)).

In the developing step, surface portions not sufficiently cured of the photosensitive layer 215 exposed in the second exposing step are removed. Specifically, surface portions not sufficiently cured of the photosensitive layer 215 (surface layer including the conductive layer 213) are removed by development. Thereby, the conductive pattern 213a having a predetermined pattern is left on a resin cured layer 215a in the region exposed in the first exposing step and the second exposing step, and the resin cured layer 215a not covered with the conductive layer 213 is formed at the portions removed in the developing step. By such a method, a height H of the conductive pattern 213a disposed on the resin cured layer 215a is reduced as illustrated in FIG. 3(d).

<Electronic Component and its Production Method>

The electronic component of the present embodiment comprises a substrate with a cured film, such as the patterned substrate or the conductive patterned substrate of the present embodiment. The substrate with a cured film comprises a cured film comprising a cured product of the photosensitive resin composition of the present embodiment on a substrate (for example, a transparent substrate). In the electronic component of the present embodiment, the cured film can be used as a protective member (such as a protective film), an insulating member (such as an insulating film) or the like, for example.

Examples of the electronic component of the present embodiment include touch panels, liquid crystal displays, organic electroluminescent displays, solar cell modules, printed circuit boards, and electronic paper.

Hereinafter, the electronic component and its production method (examples of use of the cured film pattern, places in which the cured film is used) of the present embodiment will be further described.

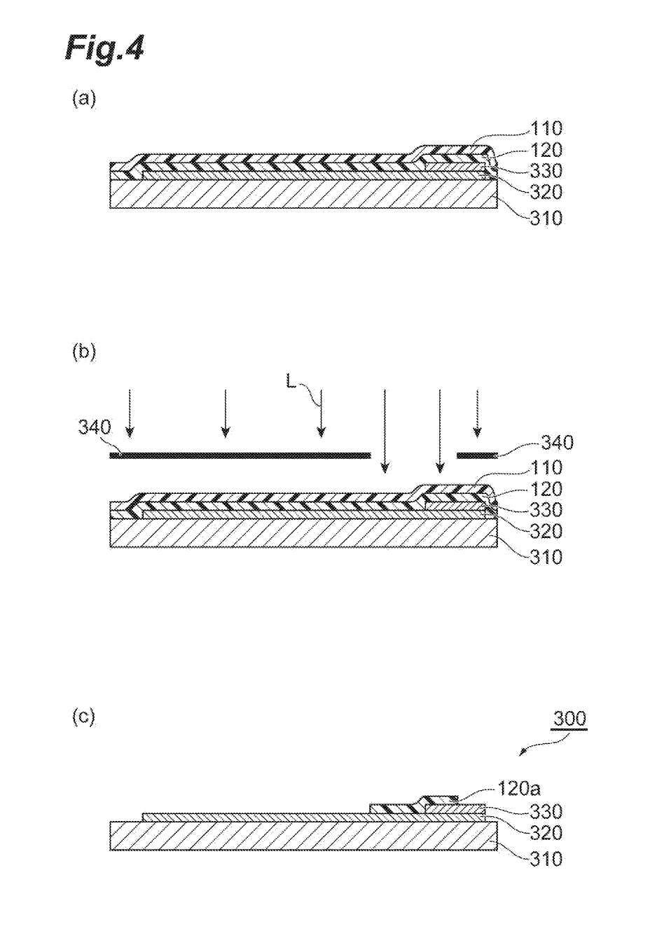

Using FIG. 4, one example of a touch panel obtained by using the photosensitive film 100 (FIG. 1) and its production method will be described as a first embodiment of an electronic component obtained by using a photosensitive film and its production method. FIG. 4 is a schematic sectional view for describing a method of producing a substrate for a touch panel provided with a cured film (protective film).

First, after the protective film 130 of the photosensitive film 100 is peeled off, as illustrated in FIG. 4(a), the support film 110 and the photosensitive layer 120 are laminated on electrodes (electrodes for a touch panel) 320 and 330 disposed on a substrate (substrate for a touch panel; such as a transparent substrate) 310. Subsequently, as illustrated in FIG. 4(b), predetermined portions of the photosensitive layer 120 are irradiated with active light beams L through a photomask 340 to form photocured portions. After irradiation with the active light beams L, portions other than the photocured portions of the photosensitive layer 120 (portions not irradiated with the active light beams L of the photosensitive layer 120) are removed. Thereby, as illustrated in FIG. 4(c), a protective film 120a covering at least part of the electrodes 320 and 330 is formed. Thus, a substrate for a touch panel provided with a cured film (protective film) 300 is obtained.

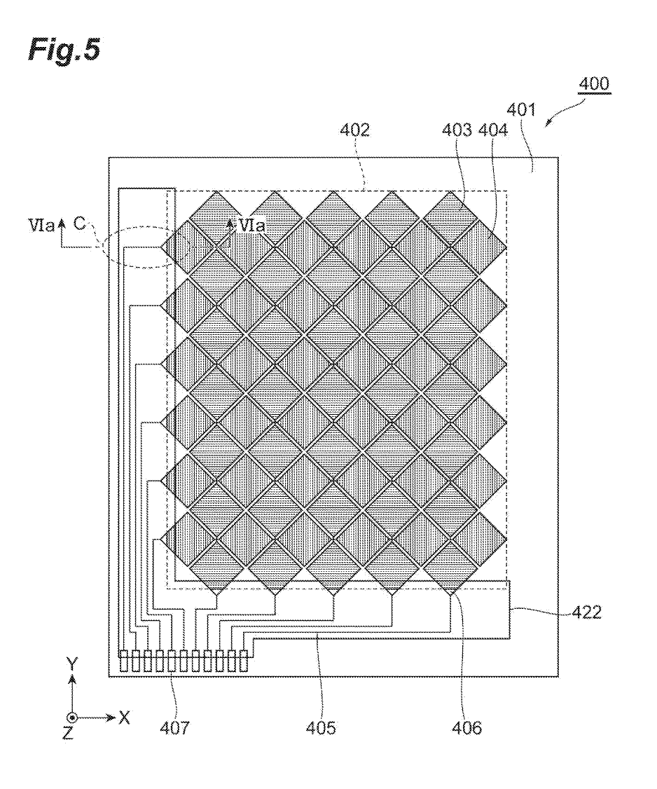

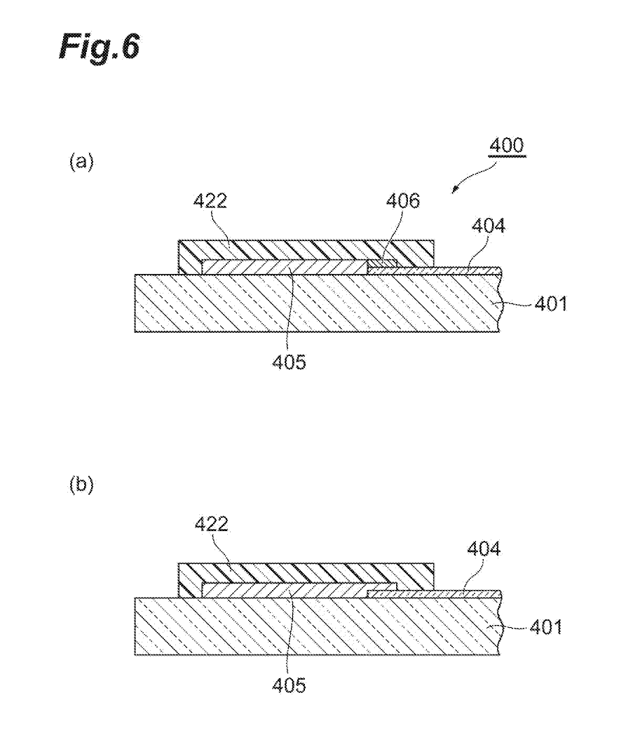

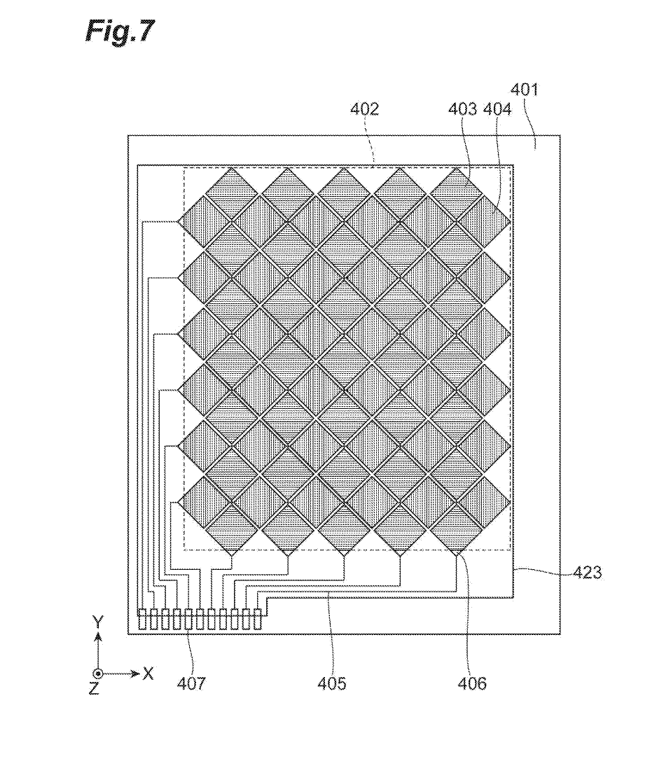

Next, using FIGS. 5 to 7, one example of a touch panel and its production method will be described as a second embodiment of an electronic component, obtained by using a photosensitive film, and its production method. FIG. 5 is a schematic plan view illustrating one example of a capacitive touch panel. FIG. 6 is a partial sectional view illustrating one example of a capacitive touch panel, FIG. 6(a) is a partial sectional view taken along the line VIa-VIa of the region C in FIG. 5, and FIG. 6(b) is a partial sectional view illustrating an aspect different from that of FIG. 6(a). FIG. 7 is a schematic plan view illustrating another example of the capacitive touch panel.

A touch panel (capacitive touch panel) 400 illustrated in FIGS. 5 and 6(a) comprises a touch screen 402 for detecting touch position coordinates on one surface of a transparent substrate 401. Transparent electrodes 403 and transparent electrodes 404 for detecting a change in electrostatic capacitance in the region of the touch screen 402 are alternatingly disposed on the transparent substrate 401. The transparent electrodes 403 and 404 each detect a change in electrostatic capacitance of the touch position. Thereby, the transparent electrodes 403 detect signals indicating the X position coordinate, and the transparent electrodes 404 detect signals indicating the Y position coordinate.

Drawing wires 405 for transmitting a detected signal at the touch position, which has been detected by the transparent electrodes 403 and 404, to an external circuit are disposed on the transparent substrate 401. The drawing wires 405 are directly connected to the transparent electrodes 403 and 404, and are also connected through connection electrodes 406 disposed on the transparent electrodes 403 and 404 (see FIG. 6(a)). As illustrated in FIG. 6(b), the drawing wires 405 may be directly connected to the transparent electrodes 403 and 404 rather than through the connection electrodes 406. One ends of the drawing wires 405 are connected to the transparent electrodes 403 and 404, and the other ends of the drawing wires 405 are connected to connection terminals 407 for connecting to an external circuit.

A protective film 422 is disposed on the drawing wires 405, the connection electrodes 406 and the connection terminals 407. In the partial sectional view illustrated in FIG. 6(a), part of the transparent electrodes 404 and all of the drawing wires 405 and the connection electrodes 406 are covered with the protective film 422. The photosensitive resin composition and the photosensitive film of the present embodiment can be suitably used to form a cured product (cured film pattern) as the protective film 422 for protecting the drawing wires 405, the connection electrodes 406 and the connection terminals 407.

Moreover, such a protective film 422 can also protect electrodes in the sensing region at the same time. For example, in FIG. 5, the drawing wires 405, the connection electrodes 406, part of electrodes in the sensing region, and part of the connection terminals 407 are protected by the protective film 422. The position in which the protective film is disposed may be appropriately varied. For example, as illustrated in FIG. 7, a protective film 423 may be disposed so as to protect the entire touch screen 402.

The touch panel can be manufactured, for example, in the same manner as in the method of producing a substrate for a touch panel provided with a cured film described above (FIG. 4). A method of producing the touch panel 400 using the photosensitive film or the photosensitive conductive film of the present embodiment will be specifically described. First, the transparent electrodes 403 for detecting the X position coordinate are formed on the transparent substrate 401. Subsequently, the transparent electrodes 404 for detecting the Y position coordinate are formed with an insulating layer (not illustrated) interposed. As the method of forming the transparent electrodes 403 and 404, for example, a method of etching a transparent electrode layer disposed on the transparent substrate 401 can be used. Moreover, transparent electrodes can also be formed using the photosensitive conductive film of the present embodiment.

Next, the drawing wires 405 for connecting to an external circuit, and the connection electrodes 406 connecting the drawing wires 405 to the transparent electrodes 403 and 404 are formed on the transparent substrate 401. The drawing wires 405 and the connection electrodes 406 may be formed after formation of the transparent electrodes 403 and 404, or may be formed simultaneously with formation of the transparent electrodes 403 and 404. As the method of forming the drawing wires 405 and the connection electrodes 406, a method of etching after metal sputtering can be used, for example. The drawing wires 405 can be formed simultaneously with formation of the connection electrodes 406 using a conductive paste material containing silver flakes by screen printing, for example. Next, the connection terminals 407 for connecting the drawing wires 405 to an external circuit are formed.

The photosensitive layer 120 of the photosensitive film of the present embodiment is press bonded so as to cover the transparent electrodes 403, the transparent electrodes 404, the drawing wires 405, the connection electrodes 406 and the connection terminals 407 formed on the transparent substrate 401 by the steps above, to transfer the photosensitive layer 120 onto these constitutional members. Next, the photosensitive layer 120 is irradiated with the active light beams L through a photomask having a desired shape into the pattern to form photocured portions. After the irradiation with the active light beams L, development is performed to remove portions other than the photocured portions in the photosensitive layer 120. Thereby, the protective film 422 consisting of the photocured portions of the photosensitive layer 120 is formed. Thus, the touch panel 400 comprising the protective film 422 (touch panel comprising the substrate for a touch panel provided with the protective film 422) can be produced.

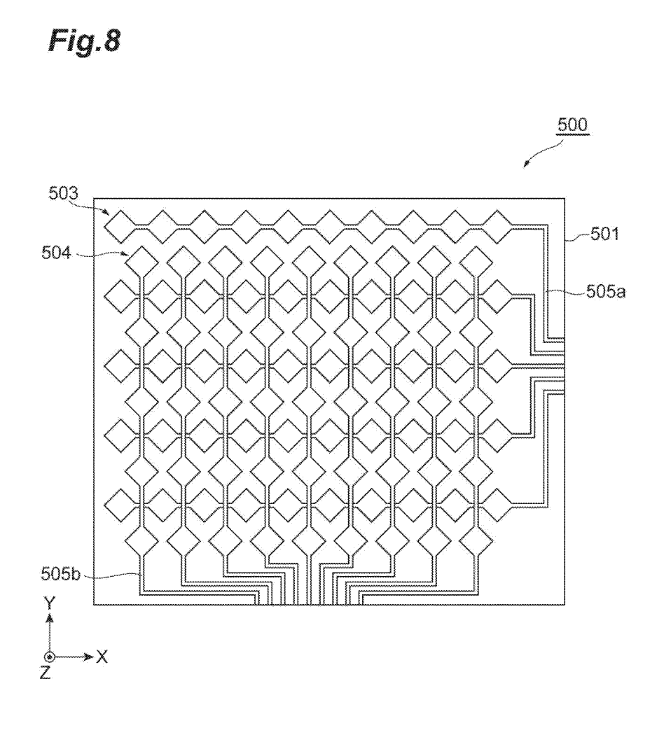

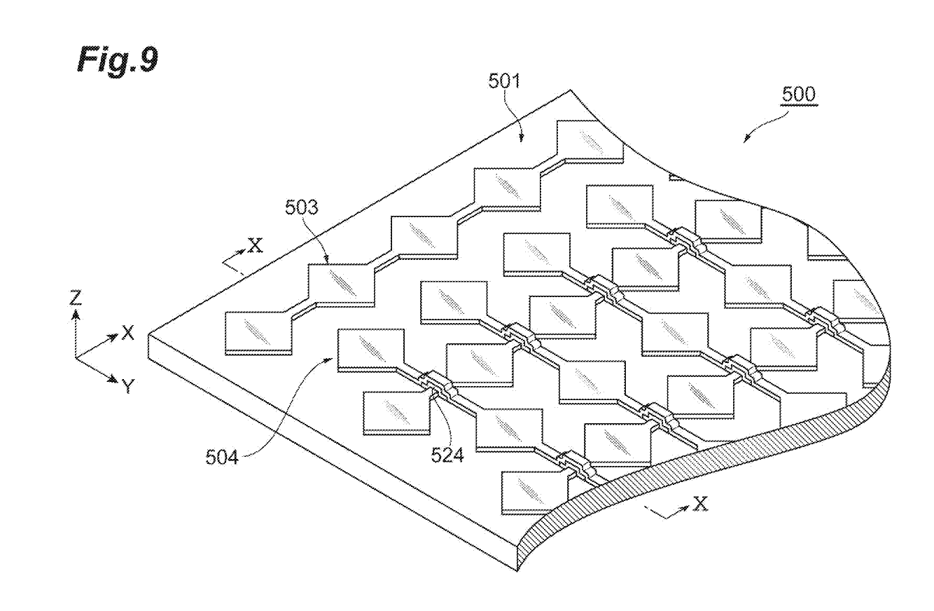

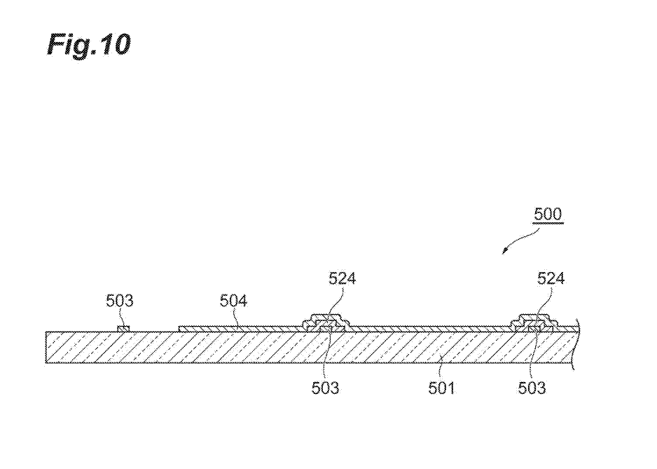

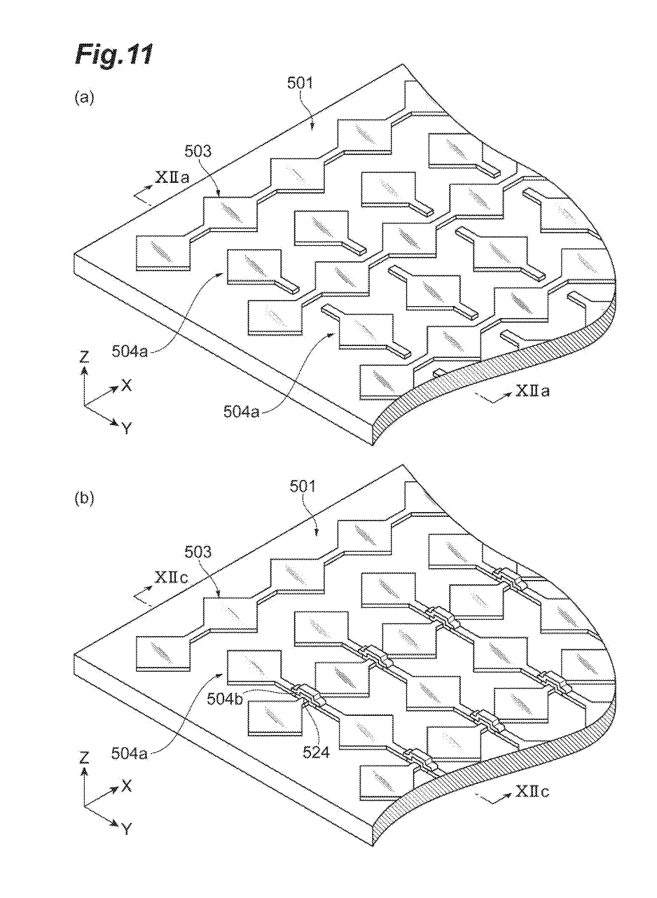

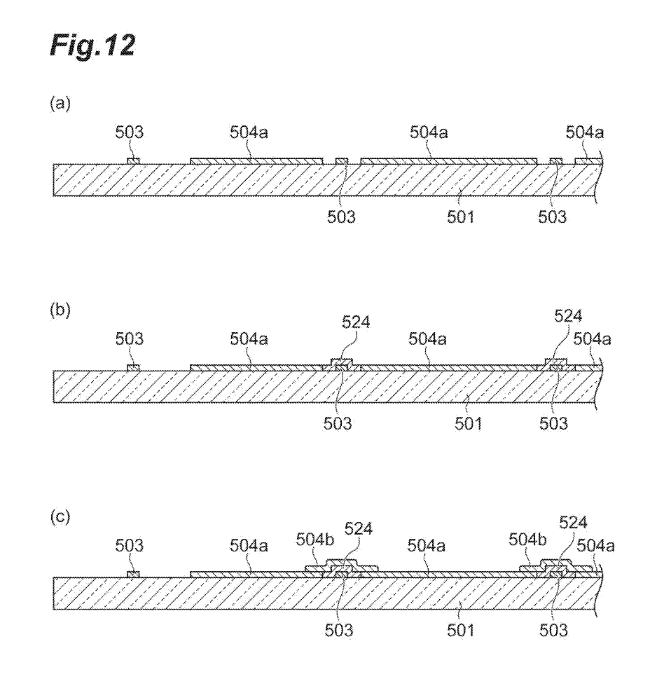

Next, using FIGS. 8 to 12, one example of a capacitive touch panel, having transparent electrodes present on the same plane, and its production method will be described as a third embodiment of the electronic component, obtained by using a photosensitive film or a photosensitive conductive film, and its production method. FIG. 8 is a schematic plan view illustrating one example of a touch panel. FIG. 9 is a partially cut-out perspective view of FIG. 8. FIG. 10 is a partial sectional view taken along the line X-X of FIG. 9. FIG. 11 is a partially cut-out perspective view for describing a method of producing a touch panel, FIG. 11(a) is a partially cut-out perspective view illustrating a substrate comprising transparent electrodes, and FIG. 11(b) is a partially cut-out perspective view illustrating a capacitive touch panel. FIG. 12 is a partial sectional view for describing a method of producing a touch panel, FIG. 12(a) is a partial sectional view taken along the line XIIa-XIIa of FIG. 11(a), FIG. 12(b) is a partial sectional view illustrating the steps of forming an insulating film, and FIG. 12(c) is a partial sectional view taken along the line XIIc-XIIc of FIG. 11(b).

A touch panel (capacitive touch panel) 500 illustrated in FIGS. 8 to 10 comprises transparent electrodes 503 and transparent electrodes 504 for detecting a change in capacitance on a transparent substrate 501. The transparent electrodes 503 detect signals indicating the X position coordinate. The transparent electrodes 504 detect signals indicating the Y position coordinate. The transparent electrodes 503 and the transparent electrodes 504 are present on the same plane. Drawing wires 505a and drawing wires 505b for connecting to a control circuit of a driver element circuit (not illustrated) that controls electric signals as a touch panel are connected to the transparent electrodes 503 and 504. An insulating film 524 is disposed between the transparent electrodes 503 and the transparent electrodes 504 at the intersection of the transparent electrodes 503 and the transparent electrodes 504.

A method of producing the touch panel 500 will be described using FIGS. 11 and 12. In the method of producing the touch panel 500, for example, a substrate on which the transparent electrodes 503, and conductive material portions for foaming the transparent electrodes 504 are preliminarily formed on the transparent substrate 501 by a known method using a transparent conductive material may be used. For example, as illustrated in FIGS. 11(a) and 12(a), a substrate on which the transparent electrodes 503, and conductive material portions 504a for forming the transparent electrodes 504 are preliminarily formed is prepared. The transparent electrodes 503 and the transparent electrodes 504 may be formed using the photosensitive conductive film of the present embodiment.

Next, as illustrated in FIG. 12(b), a photosensitive layer comprising the photosensitive resin composition of the present embodiment is disposed on parts of the transparent electrodes 503, which are to serve as the intersection of the transparent electrodes 503 and the transparent electrodes 504 (portions of the transparent electrodes 503 between the conductive material portions 504a), and exposure and development are performed to form the insulating film 524. Subsequently, as illustrated in FIGS. 11(b) and 12(c), a conductive pattern is formed on the insulating film 524 as bridge portions 504b of the transparent electrodes 504 by a known method. The conductive material portions 504a are electrically conducted through the bridge portions 504b to form the transparent electrodes 504. Then, the drawing wires 505a and 505b are formed to obtain the touch panel 500. The photosensitive film of the present embodiment can be suitably used as the insulating film 524 to form a cured product (cured film pattern).

For example, the transparent electrodes 503 and 504 may be formed by a known method using ITO or the like, or may be formed using the photosensitive conductive film of the present embodiment. The drawing wires 505a and 505b can be formed by a known method using a transparent conductive material, a metal such as Cu or Ag, or the like. Moreover, a substrate on which the drawing wires 505a and 505b are preliminarily formed may be used in the method of producing the touch panel 500.

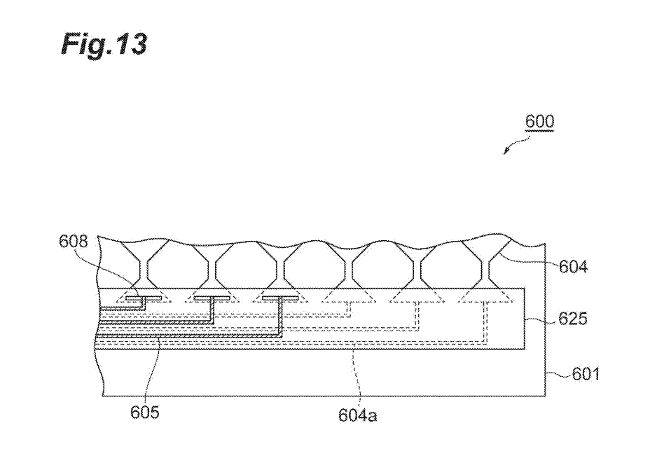

Next, using FIG. 13, one example of a touch panel will be described as a fourth embodiment of the electronic component. FIG. 13 is a partial plan view illustrating one example of a touch panel. In a touch panel 600 illustrated in FIG. 13, a narrow frame of the touch panel is intended.

The touch panel 600 comprises a transparent substrate 601, transparent electrodes 604, wires (transparent electrode wires) 604a, drawing wires 605, and an insulating film (insulating film, such as a transparent insulating film) 625. The transparent electrodes 604 and the wires 604a are disposed on the transparent substrate 601. The wires 604a extend from the transparent electrodes 604. The insulating film 625 is disposed on ends of the transparent electrodes 604 and the wires 604a. The drawing wires 605 are disposed on the insulating film 625. Openings 608 are formed in the insulating film 625 above the ends of some of the transparent electrodes 604. The transparent electrodes 604 and the drawing wires 605 are connected and electrically conducted through the openings 608. The photosensitive film of the present embodiment can be suitably used as the insulating film 625 to form a cured product (resin cured film pattern).

### EXAMPLES

Hereinafter, the present invention will be more specifically described by way of Examples. It should be noted that the present invention is not limited to the Examples below.

[Synthesis of Photopolymerization Initiator]

4,4′-Difluorobenzophenone was dissolved in DMAc (dimethylacetamide) in a flask provided with a stirrer, a reflux cooler, an inert gas introducing port and a thermometer. Next, after thiophenol (2 mol relative to 1 mol of 4,4′-difluorobenzophenone) was added, the temperature was raised to 60° C. under a nitrogen gas atmosphere, and stirring was performed for 3 hours. After cooling to room temperature (25° C., the same was true below), the solvent was removed to yield a yellow solid of a phenyl sulfide compound. After acetyl chloride (2 mol relative to 1 mol of 4,4′-difluorobenzophenone) was added to the solid, stirring was performed at room temperature for 24 hours. After water was added to the reaction mixture, the product was extracted with ethyl acetate, and was condensed to yield a light yellow solid of an acyl product. After the solid obtained was dissolved in DMAc, hydrochloric acid and sodium acetate were added. Next, hydroxylamine (2 mol relative to 1 mol of 4,4′-difluorobenzophenone) was added, and stirring was then performed at 80° C. for 5 hours. After water was added to the reaction mixture, the product was extracted with ethyl acetate, and was condensed to yield a light yellow solid of an oxime product. After the oxime product was dissolved in DMAc, acetic anhydride (2 mol relative to 1 mol of 4,4′-difluorobenzophenone) was added. Next, after stirring was performed at 90° C. for 1 hour, cooling was performed. After neutralization was performed with an aqueous solution of 5% by mass sodium hydroxide, washing was performed with water. Next, the product was extracted with ethyl acetate, and was condensed to yield a light yellow solid of an oxime ester product. The light yellow solid was subjected to ¹H-NMR analysis; it was confirmed that a compound represented by the following formula (C1) was yielded as a photopolymerization initiator for the target product.

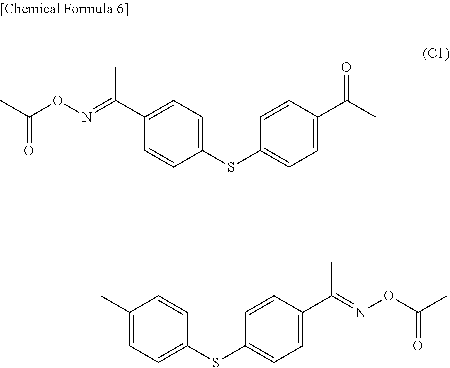

[Preparation of Binder Polymer Solution (A1)]

The materials (1) shown in Table 1 were placed in a flask provided with a stirrer, a reflux cooler, an inert gas introducing port and a thermometer, and the temperature was then raised to 80° C. under a nitrogen gas atmosphere. While the reaction temperature was kept at 80° C.±2° C., the materials (2) shown in Table 1 were uniformly added dropwise for 4 hours. After the materials (2) were added dropwise, stirring was continued at 80° C.±2° C. for 6 hours to yield a solution of a binder polymer having a weight average molecular weight (Mw) of 65,000 (solid content: 45% by mass) (A1).

The weight average molecular weight was obtained by the measurement with gel permeation chromatography (GPC) and conversion with calibration curves of standard polystyrenes. GPC measurement conditions are shown below.

### [GPC Measurement Conditions]

pump: Hitachi L-6000 (manufactured by Hitachi, Ltd., product name)

columns: Gelpack GL-R420, Gelpack GL-R430, Gelpack GL-R440 (manufactured by Hitachi Chemical Company, Ltd., product name)

eluent: tetrahydrofuran

measurement temperature: 40° C.

sample concentration: 120 mg of a resin solution having a NV (non-volatile concentration) of 50% by mass was collected, and was dissolved in 5 mL of THF.

amount of injection: 200 μL

pressure: 4.9 MPa

flow rate: 2.05 mL/min

detector: Hitachi L-3300 RI (manufactured by Hitachi, Ltd., product name)

TABLE 1

| Materials | | Amount (parts by mass) |
|---|---|---|
| (1) | Propylene glycol monomethyl ether | 75 |
| | Toluene | 49 |
| (2) | Methacrylic acid | 12 |
| | Methyl methacrylate | 58 |
| | Ethyl acrylate | 30 |
| | 2,2′-Azobis(isobutyronitrile) | 1 |

### Example 1

### [Preparation of Photosensitive Resin Composition Solution]

While stirring was being performed with a stirrer, the materials shown in Table 2 were mixed for 15 minutes to prepare a photosensitive resin composition solution for a photosensitive film. Trimethylolpropane triacrylate (TMPTA, manufactured by NIPPON KAYAKU Co., Ltd.) was used as the component (B). Octamethylcyclotetrasiloxane (8032 ADDITIVE, manufactured by Dow Corning Toray Co., Ltd.) and methyl ethyl ketone (manufactured by Tonen Chemical Corporation) were used as other components. In Table 2, the amount of binder polymer solution (A1) indicates the amount of only the solid content.

[Preparation of Photosensitive Film V-1]

A coating solution consisting of the photosensitive resin composition solution prepared above was uniformly applied onto a support film (polyethylene terephthalate film having a thickness of 50 μm) with a comma coater. Subsequently, the solvent was removed by drying with a hot air convection dryer at 100° C. for 10 minutes to form a photosensitive layer. Subsequently, the photosensitive layer was covered with a protective film (polyethylene film, manufactured by TAMAPOLY CO., LTD., product name “NF-13”) to prepare photosensitive film V-1. The film thickness after drying of the photosensitive layer was 5 μm.

<Evaluation of Photosensitive Film V-1>

### [Evaluation of Sensitivity]

While the polyethylene film (protective film) of photosensitive film V-1 was being peeled, a laminate of the photosensitive layer and the support film was laminated on a PET film (manufactured by TOYOBO CO., LTD., product name A4300, length of 12 cm×width of 12 cm, thickness: 125 μm) so as to bring the photosensitive layer into contact with the PET film using a laminator (manufactured by Hitachi Chemical Company, Ltd., product name HLM-3000) under the conditions at a roll temperature of 110° C., a substrate feeding rate of 1 m/min and a press bonding pressure (cylinder pressure) of 4×10⁵ Pa to prepare a laminate in which the support film, the photosensitive layer and the PET film were laminated.

Next, a negative mask having 41-stage step tablet was closely adhered to the support film, and the photosensitive layer of the obtained laminate was irradiated with ultraviolet light from the support film side (above the photosensitive layer side) at an amount of exposure of 50 mJ/cm² (measured value of i rays (wavelength: 365 nm)) using a parallel light exposing apparatus (manufactured by ORC MANUFACTURING CO., LTD., EXM1201).

After exposure, it was left at room temperature for 15 minutes. Subsequently, an aqueous solution of 1% by mass sodium carbonate was sprayed at 30° C. for 30 seconds to perform development. A photosensitive pattern was formed on the PET film through development. The sensitivity was evaluated according to the number of remaining step stages after development. The sensitivity was evaluated as 20 stages.

[Measurement of b*]

While the polyethylene film (protective film) of photosensitive film V-1 was being peeled, a laminate of the photosensitive layer and the support film was laminated on a glass substrate having a thickness of 0.7 mm (b*: 0.1 to 0.2) so as to bright the photosensitive layer into contact with the substrate using a laminator (manufactured by Hitachi Chemical Company, Ltd., product name HLM-3000) under conditions at a roll temperature of 110° C., a substrate feeding rate of 1 m/min and a press bonding pressure (cylinder pressure) 4×10⁵ Pa to prepare a laminate in which the support film, the photosensitive layer and the glass substrate were laminated.

Next, the photosensitive layer of the obtained laminate was irradiated with ultraviolet light from the support film side (above the photosensitive layer side) at an amount of exposure of 50 mJ/m² (measured value of i rays (wavelength: 365 nm)) using a parallel light exposing apparatus (manufactured by ORC MANUFACTURING CO., LTD., EXM1201). After the support film was removed, ultraviolet light was irradiated from above the photosensitive layer side at an amount of exposure of 1000 mJ/cm² (measured value of i rays). Thereby, a sample for measuring b* having a protective film (cured film) consisting of a cured product of a photosensitive layer having a thickness of 5.0 μm was obtained.

Next, the b* in the CIELAB color system of the obtained sample at a light source setting D65 and a viewing angle of 2° was measured using a spectrocolorimeter “CM-5” manufactured by KONICA MINOLTA, INC. The b* of the cured film was 0.7, and therefore, it was confirmed that the cured film had a good b*.

### Comparative Examples 1 to 3

Photosensitive films were prepared in the same manner as in Example 1 except that the photosensitive resin composition solutions shown in Table 2 were used, and the sensitivity and the b* in the CIELAB color system were evaluated. As the photopolymerization initiator, 1-[4-(phenylthio)phenyl]-1,2-octanedione 2-(O-benzoyloxime) (OXE-01, manufactured by BASF SE), 1-[9-ethyl-6-(2-methylbenzoyl)-9H-carbazol-3-yl] ethanone O-acetyloxime (OXE-02, manufactured by BASF SE), and diphenyl-2,4,6-trimethylbenzoylphosphine oxide (Lucirin (registered trademark) TPO, manufactured by BASF SE) were used. The results are shown in Table 2.

TABLE 2

| | | | Amount (parts by mass) | | | |
|---|---|---|---|---|---|---|
| | | | | Comparative | Comparative | Comparative |
| | Components | Materials | Example 1 | Example 1 | Example 2 | Example 3 |
| Photosensitive | (A) | (A1) | 60 | 60 | 60 | 60 |
| resin | (B) | Trimethylolpropane triacrylate | 40 | 40 | 40 | 40 |
| composition | (C) | (C1) | 1.5 | — | — | — |
| solution | | 1-[4-(Phenylthio)phenyl]-1,2- | — | 1.5 | — | — |
| | | octanedione 2-(O-benzoyloxime) | | | | |
| | | 1-[9-Ethyl-6-(2-methylbenzoyl)- | — | — | 1.5 | — |
| | | 9H-carbazol-3-yl]ethanone | | | | |
| | | O-acetyloxime | | | | |
| | | Diphenyl-2,4,6- | — | — | — | 5 |
| | | trimethylbenzoyl-phosphine | | | | |
| | | oxide | | | | |
| | Others | Octamethylcyclotetrasiloxane | 0.1 | 0.1 | 0.1 | 0.1 |
| | | Methyl ethyl ketone | 50 | 50 | 50 | 50 |

| | | | | | |
|---|---|---|---|---|---|
| Results of | Sensitivity (stages) | 20 | 19 | 30 | 5 |
| evaluation | b* | 0.7 | 1.1 | 3.2 | 0.6 |

As shown in Table 2, in the Examples, it was confirmed that high sensitivity and low b* were achieved, and high sensitivity and high transparency were satisfied at the same time. In contrast, in the Comparative Examples, it was difficult to satisfy high sensitivity and high transparency at the same time.

### INDUSTRIAL APPLICABILITY

The photosensitive resin composition of the present invention can be used as a photosensitive material which high transparency is required for electrode wires in flat panel displays such as liquid crystal display elements; touch panels (touch screens); and devices such as solar cells and lightings.

### REFERENCE SIGNS LIST

100 . . . photosensitive film, 110 . . . support film, 120, 215, 223 . . . photosensitive layer, 120a, 422, 423 . . . protective film, 130 . . . protective film, 210, 220 . . . photosensitive conductive film, 211, 221 . . . support film, 213, 225 . . . conductive layer, 213a . . . conductive pattern, 215a . . . resin cured layer, 230 . . . substrate, 240, 340 . . . photomask, 250 . . . conductive patterned substrate, 300 . . . substrate for a touch panel provided with a cured film, 310 . . . substrate, 320, 330 . . . electrode, 400, 500, 600 . . . touch panel, 401, 501, 601 . . . transparent substrate, 402 . . . touch screen, 403, 404, 503, 504, 604 . . . transparent electrode, 405, 505a, 505b, 605 . . . drawing wire, 406 . . . connection electrode, 407 . . . connection terminal, 504a . . . conductive material portion, 504b . . . bridge portion, 524, 625 . . . insulating film, 604a . . . wire (transparent electrode wire), 608 . . . opening.

1. A photosensitive resin composition, comprising a binder polymer, a photopolymerizable compound, and a photopolymerization initiator,
wherein the photopolymerization initiator contains a compound represented by the following general formula (1): 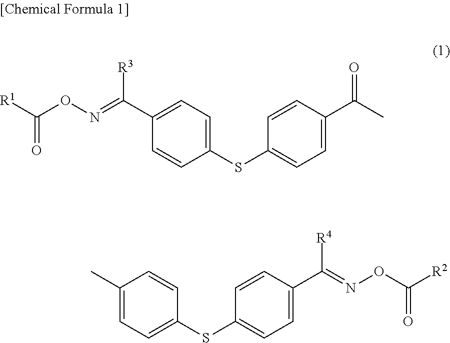
[In the formula (1), R¹, R², R³ and R⁴ each independently represent an alkyl group, an aryl group, an aralkyl group, —OR⁵, —COOR⁶ or —OCOR⁷; and R⁵, R⁶ and R⁷ each independently represent an alkyl group, an aryl group or an aralkyl group.]

2. A photosensitive resin composition, comprising a photopolymerizable compound and a photopolymerization initiator,
wherein the photopolymerization initiator contains a compound represented by the following general formula (1): 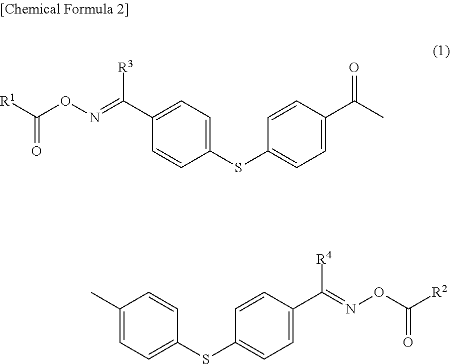
[In the formula (1), R¹, R², R³ and R⁴ each independently represent an alkyl group, an aryl group, an aralkyl group, —OR⁵, —COOR⁶ or —OCOR⁷; and R⁵, R⁶ and R⁷ each independently represent an alkyl group, an aryl group or an aralkyl group.]

3. A photosensitive film, comprising a support film, and a photosensitive layer disposed on the support film,
wherein the photosensitive layer comprises the photosensitive resin composition according to claim 2.

4. The photosensitive film according to claim 3, wherein a thickness of the photosensitive layer is 15 μm or less.

5. A patterned substrate, comprising a substrate, and a pattern disposed on the substrate,
wherein the pattern comprises a cured product of the photosensitive resin composition according to claim 2.

6. A patterned substrate, comprising a substrate, and a pattern disposed on the substrate,
wherein the pattern comprises a cured product of the photosensitive resin composition of the photosensitive film according to claim 3.

7. A photosensitive conductive film for forming a conductive pattern, comprising a support film, a conductive layer disposed on the support film, and a photosensitive layer disposed on the conductive layer,
wherein the photosensitive layer comprises the photosensitive resin composition according to claim 2.

8. A photosensitive conductive film for forming a conductive pattern, comprising a support film, a photosensitive layer disposed on the support film, and a conductive layer disposed on the photosensitive layer,
wherein the photosensitive layer comprises the photosensitive resin composition according to claim 2.

9. The photosensitive conductive film according to claim 7, wherein a thickness of the photosensitive layer is 15 μm or less.

10. The photosensitive conductive film according to claim 7, wherein the conductive layer comprises conductive fibers.

11. The photosensitive conductive film according to claim 10, wherein the conductive fibers contain silver fibers.

12. A conductive patterned substrate, comprising a substrate, and a conductive pattern disposed on the substrate,
wherein the conductive pattern comprises a cured product of the photosensitive resin composition of the photosensitive conductive film according to claim 7.

13. The photosensitive conductive film according to claim 8, wherein a thickness of the photosensitive layer is 15 μm or less.

14. The photosensitive conductive film according to claim 8, wherein the conductive layer comprises conductive fibers.

15. The photosensitive conductive film according to claim 14, wherein the conductive fibers contain silver fibers.

16. A conductive patterned substrate, comprising a substrate, and a conductive pattern disposed on the substrate,
wherein the conductive pattern comprises a cured product of the photosensitive resin composition of the photosensitive conductive film according to claim 8.
